(19) United States
(12) Patent Application Publication
(10) Pub. No.: US 2006/0236935 A1
(43) Pub. Date: Oct. 26, 2006

(54) Coating installation with coolable diaphragm

(75) Inventors: Jochen Krause, Dresden (DE); Joern Brueckner, Grossschirma (DE); Dietmar Schulze, Dresden (DE); Falk Milde, Dresden (DE)

Correspondence Address: BAKER & BOTTS, 30 ROCKEFELLER PLAZA, 44TH FLOOR, NEW YORK, NY, 10112, US

(73) Assignee: Von Ardenne Anlagentechnik GmbH

(21) Appl. No.: 11/243,039

(22) Filed: Oct. 4, 2005

(30) Foreign Application Priority Data
Apr. 25, 2005 (DE) 10 2005 019 417.6

(51) Int. Cl. C23C 16/00

(52) U.S. Cl. 118/724

(57) ABSTRACT

A coating installation is provided with diaphragms that are convenient to mechanically install and remove. A coating installation, which has a coating chamber delimited by chamber walls, has at least one cooling device arranged on a chamber wall. A bracket in thermal contact with the cooling device, is configured with a bearing surface to receive the diaphragm. The bearing surface may be a horizontal or an inclined surface on which the diagram can be lowered or pressure fitted so that it is in thermal contact with the bracket. In coating installation operation, heat is conducted from the diagram to the cooling device through the bracket.

### CROSS REFERENCE TO RELATED APPLICATIONS

This application claims the benefit of German Patent Application No. 10 2005 019 417.6 filed Apr. 25, 2005 which application is hereby incorporated by reference in its entirety herein.

### FIELD OF THE INVENTION

The invention relates material processing systems and techniques for coating industrial articles or substrates. In particular, the invention relates to apparatus or installations vapor deposition of coating materials on industrial articles or substrates.

### BACKGROUND OF THE INVENTION

Diaphragms or baffles are often used in coating installations for coating substrates with coating materials by vapor deposition in order to influence the form of the stream of vapor impinging on the substrate, since the properties of the layer produced depend, inter alia, on the angle of impingement of the stream of vapor on the substrate. Furthermore, diaphragms of this type are often cooled in order to dissipate the heat formed during vaporization of the coating material from the coating installation. Within the coating installation, the diaphragms are arranged between the vaporization device and the conveyor device on which the substrates are conveyed through the coating installation.

The diaphragms or baffles are, generally following the shape of a coating chamber within the coating installation, in the shape of a rectangular diaphragm frame with a similar rectangular diaphragm opening. The rectangular diaphragm frame is formed by four angle sections, one limb of which is bolted onto a side wall or a transverse partition of the coating chamber and the other limb of which, starting from the side wall or the transverse partition, projects at right angles into the coating chamber and thereby forms one side of the rectangular diaphragm opening.

If a diaphragm of this type needs to be cooled, cooling devices with perpendicular contact surfaces, onto which the angle sections of the diaphragm arranged at the transverse partitions are directly bolted, are generally fitted to the transverse partitions of the coating chamber. This makes dismantling of the angle sections, for example for cleaning purposes, time-consuming and complicated.

Another form of a cooled diaphragm provides for the diaphragm to be designed in the style of a basket, in which case the side walls of the basket are formed in a known way from angle sections which are connected to one another and thereby form a diaphragm frame, and the base of the basket comprises a plurality of base strips that are arranged next to one another and are connected to the angle sections of the diaphragm frame. In the installed state, each base strip is positioned between in each case two rollers of a conveyor system arranged in the coating chamber, while the diaphragm frame is arranged in a known way between the vaporization device and the conveyor device.

For cooling purposes, coolant lines that are fixedly connected to the base strips and releasably connected to coolant inlets at the base of the coating chamber are arranged beneath the base strips. If the diaphragm is to be removed from the coating chamber for cleaning purposes, first of all the connections of the coolant lines to the coolant inlets have to be released. This is a complex process. Moreover, the known problem arises of it being difficult to seal connections of this type in a vacuum chamber, while possible leaks may endanger the integrity of the process.

Consideration is now being given to improving the design of diaphragm structures used in coating installations. Desirable diaphragm structures, which may be cooled, will be easy to install, clean and maintain without any adverse effect on the integrity of the coating processes.

### SUMMARY OF THE INVENTION

The present invention provides a coating installation with a coolable diaphragm. The coolable diaphragm can be fitted in a coating chamber and removed from the coating chamber when required with little difficulty.

An inventive coating installation includes a coating chamber delimited by chamber walls. One or more cooling device(s) are arranged on the chamber walls to cool diaphragm(s) disposed in the coating chamber. The diaphragm-receiving bracket thermally connects the cooling device and the diaphragm disposed in the coating chamber. The bracket may have a substantially horizontal bearing surface for receiving the diaphragm and/or an inclined bearing surface for receiving and automatically adjusting the diaphragm position. A quick-clamping means may be used for increasing the force with which a diaphragm is pressed onto the bearing surface. Suitable contact producing means may be deployed to enhance the thermal contact between the diaphragm and the bearing surface.

In one version of the coating chamber, a cooling device extends all the way around the inside of the coating chamber along all of the chamber walls delimiting the coating chamber. In another version, a pair of cooling devices is disposed on a pair of opposite walls, respectively. The cooling device may be thermal conductively connected to the chamber wall(s) Insulating materials may be arranged between the one cooling device(s) and the chamber wall(s) to impede thermal conduction between the devices and the walls.

The diaphragms include suitable stop means or handles for convenient handling or manipulation of the diaphragms.

The coating installation according to the invention has at least one coating chamber delimited by chamber walls, at least one cooling device arranged in the coating chamber at a chamber wall, and a diaphragm. The diaphragm is arranged in the coating chamber so that it can be cooled by the cooling device. There is at least one bracket with good thermal conductivity in the coating chamber for receiving the diaphragm. The diaphragm can be thermally conductively connected to the bracket (i.e. placed in good thermal contact). The bracket itself is in thermal contact i.e., thermally conductively connected to the cooling device. and that

In the coating installation according to the invention, the diaphragm can be fitted in a coating chamber and removed from the coating chamber with little difficulty. For this purpose, the diaphragm is lowered into the coating chamber until it bears on the bracket. The thermal energy which is introduced into the diaphragm during the coating process is transferred to the bracket and then into the cooling device by conduction of heat. The thermal energy is transported from the cooling device out of the coating chamber in a known way by means of a circulating coolant.

An absence of the bolted connection onto a perpendicular contact surface (e.g., on the bracket) eliminates the need to insert or remove the diaphragm from the coating chamber in individual parts. This greatly reduces the time involved in fitting or removing the diaphragm. The elimination of the direct connection between diaphragm and cooling device dispenses with the bolted connections of coolant lines in the interior of the coating chamber, which are susceptible to leaks.

In one configuration of the invention, the cooling device extends all the way around the inside of the coating chamber, along all the chamber walls.

This allows efficient and powerful cooling of the diaphragm. However, this form of a cooling device, which runs all the way around the inside, may be relatively expensive.

In another configuration of the invention, a pair of cooling devices is provided at two opposite chamber walls with one cooling device on each wall.

If, by way of example, identical cooling devices are provided at the two longitudinal walls or at the two transverse partitions which separate the coating chamber from adjacent process chambers, these cooling devices can be produced at low cost and are relatively simple to fit. Moreover, this results in the possibility of using a pair of cooling devices exclusively to cool the diaphragm by virtue of them being connected in a thermally insulated manner to the corresponding chamber walls but in a thermally conductive manner to the diaphragm, whereas the other pair of cooling devices serves exclusively to cool the chamber walls by virtue of these cooling devices being thermally conductively connected to the chamber walls but connected in a thermally insulated manner to the diaphragm.

It is advantageous for the bracket to have a substantially horizontal bearing surface for receiving the diaphragm.

This simple geometry allows the use of diaphragms that are likewise of simple structure and can be placed onto the horizontal bearing surface. This represents a particularly inexpensive solution.

It is also advantageous for the bracket to have an inclined bearing surface for receiving and automatically adjusting the diaphragm.

Inclined bearing surfaces offer a number of advantages. For example, because of the cone effect, they can effect automatic centering of the diaphragm in the coating chamber. They can also produce good thermal or mechanical contact-connection of the bracket, which is responsible for a good transfer of heat.

According to a refinement of the invention, the cooling device is thermal conductively connected to the chamber wall, i.e. placed in thermal contact.

In combination with the thermally conductive connection between diaphragm and bracket, this results in the possibility of a cooling device being used simultaneously to cool the diaphragm and the chamber wall.

According to another refinement of the invention, the thermal conduction between cooling device and chamber wall is impeded by insulating materials arranged between them.

In this case, the cooling device is used exclusively to cool the diaphragm, with the result that particularly successful cooling can be achieved.

Furthermore, it is advantageous to provide a quick-clamp or other mechanical fixture for increasing the force or pressure with which the diaphragm is pressed onto the bearing surface of the bracket.

It has been found that the use of a quick-clamp, for example, a snap-action closure or latch, bolted connections, etc. for increasing the pressure with which the diaphragm is pressed onto the bracket is a suitable way of improving the conduction of heat.

Furthermore, it is advantageous for the diaphragm to have stop means or other mechanical structure for handling using lifting gear.

The provision of stop means, for example eye bolts in accordance with DIN 580, at the diaphragm allows the latter to be removed from the coating chamber or introduced into the coating chamber quickly and easily by means of a crane or other form of lifting gear.

In another advantageous configuration, contact-producing means are also provided for increasing the thermal conduction between the diaphragm and the bearing surface of the bracket.

To further boost the contact between the diaphragm and the bracket and therefore to improve the conduction of heat between them, it is expedient to provide contact-producing material, for example, thermally conductive paste or flexible tubes of woven copper.

### BRIEF DESCRIPTION OF THE DRAWINGS

Further features of the invention, its nature, and various advantages will be more apparent from the following detailed description and the accompanying drawing in which:

FIG. 1 is a schematic representation of an exemplary an information element design, in accordance with the principles of the present invention. FIG. 1 is a longitudinal section through a coating chamber of a coating installation with a diaphragm.

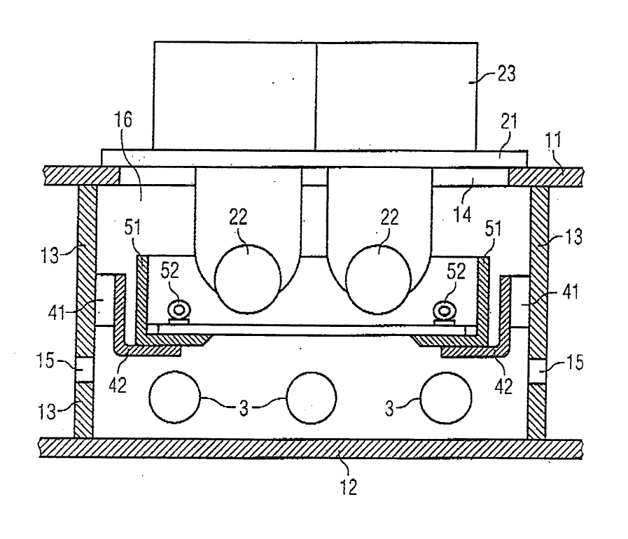

The following list is an index of the reference numerals that are used to identify elements in FIG. 1

### LIST OF REFERENCE NUMERALS

11 Cover

12 Base

13 Transverse partition

14 Opening

15 Aperture

16 Longitudinal wall

21 Magnetron covering part

22 Magnetron tube

23 Magnetron surrounding

3 Roller

41 Cooling device

42 Bracket

51 Diaphragm

52 Stop means

### DETAILED DESCRIPTION OF AN EMBODIMENT OF THE INVENTION

FIG. 1 shows a longitudinal section of an inventive coating installation/coating chamber in which the easily installed and conveniently removable diaphragms are deployed.

The coating chamber is delimited by a cover 11, a base 12, longitudinal walls 16 and two transverse partitions 13. Cover 11 has an opening 14 through which the interior of the coating chamber is accessible. The transverse partitions 13 have apertures 15, through which a substrate or work piece (not shown) is conveyed into and out of the coating chamber.

A magnetron covering part 21 is located on the cover 11. Two magnetron tubes 22 are arranged on this covering part within the coating chamber, and a magnetron surrounding 23 is arranged on the covering part outside the coating chamber.

A conveyor device including, for example, rotatably mounted rollers 3, is arranged in the coating chamber. Cooling devices 41, to each of which a bracket 42 is secured in a thermally conductive manner, are arranged at the transverse partitions 13. A diaphragm 51 is positioned in a thermally conductive manner on the brackets 42. The diaphragm 51 is arranged between the magnetron tubes 22 and the substrate plane. Brackets 42 have horizontal bearing surfaces for receiving the diaphragm 51.

Diaphragm 51 is pressed onto the brackets 42 by a quick-clamp (not shown). Furthermore, diaphragm 51 has stop means 52 allowing diaphragm 51 to be lifted out of the coating chamber.

Moreover, a contact-producing fixture or material (not shown) for improving the heat transfer is provided between the diaphragm 51 and the brackets 42.

The heat, which is introduced into diaphragm 51, is dissipated from the coating chamber by heat conduction via brackets 42 and cooling devices 41.

1.-10. (canceled)

11. A coating installation comprising:
at least one coating chamber delimited by chamber walls;
at least one cooling device arranged in the coating chamber at a chamber wall;
a diaphragm disposed in the coating chamber so that it is coolable by the cooling device; and
at least one bracket having with good thermal conductivity disposed in the coating chamber,
wherein the bracket is configured for receiving the diaphragm, wherein the bracket is thermally connected to the cooling device, and wherein the diaphragm is thermally connected to the bracket.

12. The coating installation of claim 11, wherein the cooling device extends all the way around the inside of the coating chamber along all of the chamber walls delimiting the coating chamber.

13. The coating installation of claim 11, comprising:
a first cooling device arranged at a chamber wall; and
a second cooling device arranged at a second chamber wall that is opposite to the first chamber wall.

14. The coating installation of claim 11, wherein the bracket comprises a substantially horizontal bearing surface for receiving the diaphragm.

15. The coating installation of claim 11, wherein the bracket comprises an inclined bearing surface for receiving and automatically adjusting the diaphragm.

16. The coating installation of claim 11, wherein the cooling device is thermal conductively connected to the chamber wall.

17. The coating installation of claim 11, further comprising insulating materials arranged between the at least one cooling device and the chamber wall to impede thermal conduction between the device and the wall.

18. The coating installation of claim 11, wherein the diaphragm is pressed onto a bearing surface of the bracket, the coating installation further comprising a quick-clamping means for increasing the force with which the diaphragm is pressed onto the bearing surface of the bracket.

19. The coating installation of claim 1, wherein the diaphragm comprises stop means for handling the diaphragm.

20. The coating installation of claim 11, further comprising contact producing means for increasing the thermal conduction between the diaphragm and a bearing surface of the bracket.
